(19) United States
(12) Patent Application Publication
(10) Pub. No.: US 2012/0135341 A1
(43) Pub. Date: May 31, 2012

(54) METHOD FOR DOUBLE PATTERNING LITHOGRAPHY AND PHOTOMASK LAYOUT

(75) Inventor: Yao-Ching Tseng, Taichung (TW)

(73) Assignee: Chung-Shan HO, Tainan City (TW)

(21) Appl. No.: 13/305,901

(22) Filed: Nov. 29, 2011

(30) Foreign Application Priority Data
Nov. 29, 2010 (TW) 099141211

(51) Int. Cl. G03F 7/20; G06F 17/50; G03F 1/00

(52) U.S. Cl. 430/5; 430/319; 716/55

(57) ABSTRACT

A method for double patterning lithography which is applied to a semiconductor substrate to form a plurality of trenches, includes a pattern formation process. In the pattern formation process, a plurality of predetermined patterns corresponding to the trenches are formed by using a graphic data system. A first pattern file and second pattern file are respectively formed. The first pattern file and the second pattern file respectively include a plurality of first patterns and a plurality of second patterns. The first patterns and the second patterns are intersected with each other to define a plurality of overlapped regions corresponding to the predetermined patterns. At least one of the first pattern file and the second file includes a plurality of dummy patterns therebeside. A photomask layout for double patterning lithography is also provided.

### FIELD OF THE INVENTION

The disclosure relates in general to a method for photolithography and a related photomask layout, and more particularly to a method for photolithography and a related photomask layout, which are applied in an optical proximity correction (OPC) process for double patterning lithography in semiconductor microfabrication.

### BACKGROUND OF THE INVENTION

Double patterning lithography is one of the most advanced lithography technologies in the semiconductor industry. In the field of semiconductors, a critical dimension (CD) of a semiconductor device is the width of features on the device. A pitch is generally defined as the critical dimension plus the distance to the next feature.

Referring to FIG. 1, a dielectric layer 11 of a semiconductor chip 1 is shown to include a plurality of first trenches 12 and a plurality of second trenches 13, all of which are spaced apart from each other at equal distances (d1=d2). The formation of the first and second trenches 12, 13 in semiconductor scale is preferably conducted by a double patterning lithography for forming the first trenches 12 and the second trenches 13 separately.

In detail, the conventional method for double patterning lithography is conducted as follows. Firstly, the dielectric layer 11 of the semiconductor chip 1 is prepared, and a first photomask (not shown) having a plurality of first opening patterns (not shown) is formed on the dielectric layer 11 so as to perform a first photolithography process. The dielectric layer 11 exposed from the first photomask through the first opening patterns and etching is then performed to form of the first trenches 12, followed by removing the first photomask. Then, a second photomask (not shown) having a plurality of second opening patterns (not shown) is formed on the dielectric layer 11 with the first trenches 12 thereon so as to perform a second photolithography process. The dielectric layer 11 exposed from the second photomask through the second opening patterns and etching is performed to form the second trenches 13, followed by removing the second photomask. By the above steps, the semiconductor chip 1 with the first and second trenches 12, 13 spaced apart from each other at equal distances (d1=d2) are formed.

In general, the formation of the first photomask and the formation of the second photomask include the following steps. A graphic data system (GDS) respectively generates a first GDS file including the first opening patterns corresponding to the first trenches 12 and a second GDS file including the second opening patterns corresponding to the second trenches 13. According to the first GDS file and the second GDS file, the first opening patterns and the second opening patterns are respectively written on a first substrate and a second substrate by an e-beam writing system. Thereafter, the first opening patterns and the second opening patterns are transferred onto the first substrate and the second substrate respectively by an etching process, thereby forming the first photomask and the second photomask.

However, in practice, different runs of light exposure can produce variation of the widths or critical dimensions (CD) of the first and second trenches 12, 13. Referring to FIG. 2, the distance of the first trenches 12 from the second trenches 13 can also vary (see d1′≠d2′) due to an overlay error (alignment error) that occurs during alignment of the first and second photomasks for the first and second photolithography processes. Thus, it is difficult to provide a uniform distance between the first trenches 12 and the second trenches 13, especially when the critical dimensions thereof need to be shrunk.

Moreover, since forming of the first trenches 12 and forming of the second trenches 13 are conducted separately using respective single-lithography processes, and since each of the first photomask and second photomask is photolithographed to have features not larger than 140 nm, either in width or in length directions, the photolithography resolution of the first photomask and second photomask is limited so that the first and second trenches 12, 13 are likely to have deformed corners, for example, round corners.

Furthermore, the overlay error that results in variation of the distance between the first and second trenches 12 and 13 could decrease yield rate in subsequent processes. Because shrinkage of the critical dimension (CD) contributes much influence on an overlay process, the method for double patterning lithography for the first and second trenches 12, 13 will become more and more sensitive to the overlay error when the pitch (i.e., the critical dimension (CD) of the first and second trenches 12, 13 plus the distance therebetween) of the semiconductor chip 1 is reduced further and further below 140 nm.

Additionally, in semiconductor manufacturing technology, the precision of a photolithography process significantly influences the critical dimension of the electric element. In the photolithography process, a design pattern is formed on a photomask, and an optical beam or an electronic beam is shot through the photomask to project energy thereof on a photoresist layer. Then, a developed pattern of the photoresist layer is formed after applying a development process. However, due to the influence of an optical proximity effect (OPE), the developed pattern does not always match the designed pattern. For eliminating the influence of the OPE, a designer must make a correction on the mask to reduce the difference between the developed pattern and the designed pattern. The design and correction of the photomask pattern has became a bottleneck of the development in semiconductor technology and MEMS technology.

Therefore, what is needed is a method for double patterning lithography and a photomask layout for double patterning lithography to overcome the above-mentioned shortcomings.

### SUMMARY OF THE INVENTION

The present invention provides a method for double patterning lithography with an improved function of critical dimension shrinkage, with a wider tolerance range of overlay error (alignment error) and more critical dimension control accuracy by dummy patterns.

The present invention provides a photomask layout for double patterning lithography with an improved function of critical dimension shrinkage, with a wider tolerance range of overlay error (alignment error) and more critical dimension control accuracy by dummy patterns.

The present invention provides a method for double patterning lithography of the present invention, which is applied to a semiconductor substrate to form a plurality of trenches, includes a pattern formation process. The pattern formation process includes the following steps. A plurality of predetermined patterns corresponding to the trenches are formed by using a graphic data system. A first pattern file is formed by using the graphic data system. The first pattern files include a plurality of first patterns. A second pattern file is formed by using the graphic data system. The second pattern file includes a plurality of second patterns. At least one of the first pattern file and the second pattern file includes a plurality of dummy patterns therebeside. Only the first patterns and the second patterns are intersected with each other to define a plurality of overlapped regions corresponding to the predetermined patterns during overlapping the first patterns and the second patterns.

The present invention further provides a photomask layout for double patterning lithography, which is configured for forming a plurality of predetermined patterns. The photomask layout includes a plurality of first patterns, a plurality of second patterns and a plurality of dummy patterns beside at least one of the first patterns and the second patterns. Only the first patterns and the second patterns are intersected with each other to define a plurality of overlapped regions corresponding to the predetermined patterns during overlapping the first patterns and the second patterns.

### BRIEF DESCRIPTION OF THE DRAWINGS

The present invention will become more readily apparent to those ordinarily skilled in the art after reviewing the following detailed description and accompanying drawings, in which:

FIG. 1 is a schematic view to illustrate trenches of a semiconductor chip formed by a conventional method for double patterning photolithography.

FIG. 2 is a schematic view to illustrate variation of the distance between adjacent trenches of FIG. 1 resulting from an overlay error.

FIG. 3 is a flow chart showing a method for double patterning lithography according to the present invention.

FIG. 4 is a schematic view a pattern formation process according to an embodiment of the present invention.

FIGS. 5A to 5E illustrate a process flow of the photolithography process in the semiconductor process.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

According to the present invention, a method for double patterning lithography can be applied to a substrate, for example, a semiconductor substrate, to form a plurality of trenches in a plurality of predetermined positions correspondingly. It should be understood that the word “trench” as used in this context herein is used broadly such that it can indicate any type of an opening, a gap, a cavity, a hole, an empty space, or the like that can later be filled with a material, as discussed below. The method for double patterning lithography has an improved function of critical dimension shrinkage, with a wider tolerance range of overlay error (alignment error) and more critical dimension control accuracy by dummy patterns. In the present embodiment, a plurality of trenches are formed in a first material layer on a semiconductor substrate. A projection of each of the trenches on the semiconductor substrate is, but not limited to, square-like shaped.

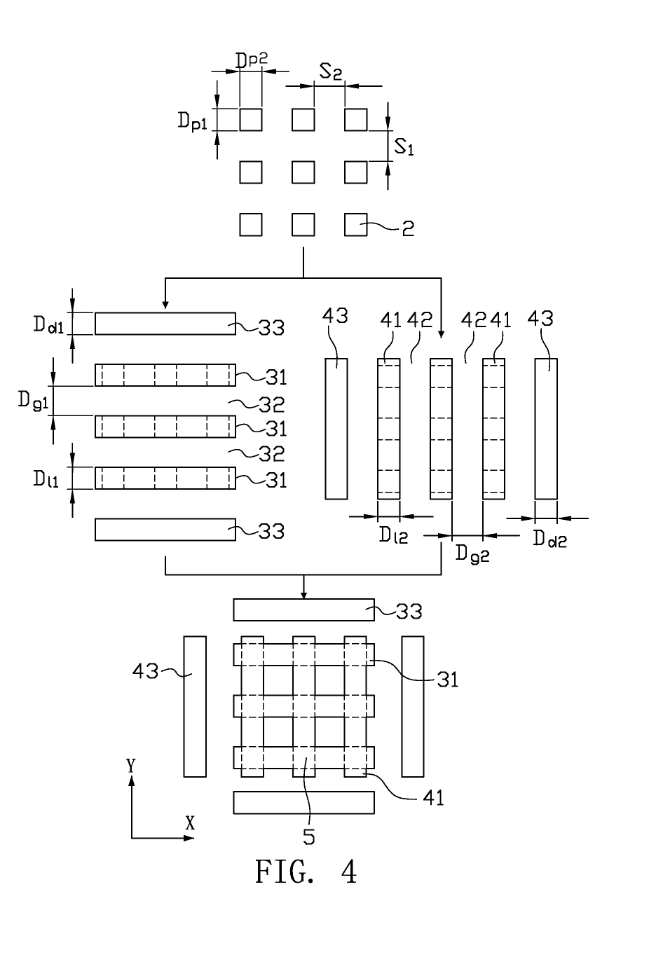

FIG. 3 is a flow chart showing a method for double patterning lithography according to the present invention. The method includes: a pattern formation process 100, a photomask formation process 200, and a photolithography process 300.

The pattern formation process 100 includes the steps of forming a plurality of predetermined patterns, forming a first pattern file and forming a second pattern file.

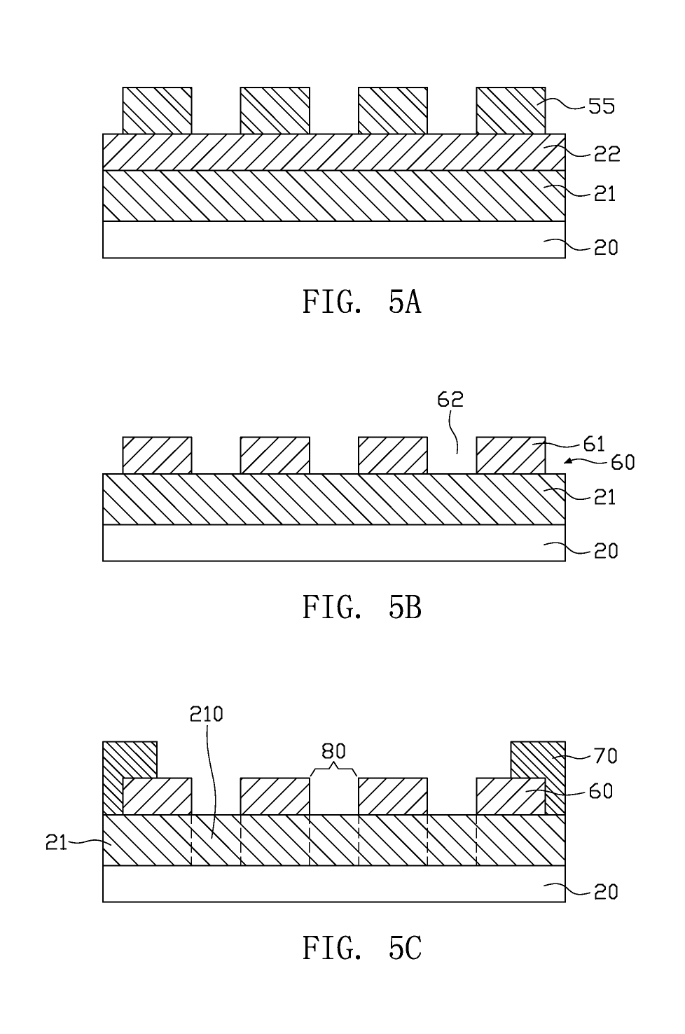

A graphic data system (GDS) generates a GDS file including a plurality of predetermined patterns 2. Referring to FIG. 4, the predetermined patterns 2 correspond to the trenches to be formed in the first material layer on the semiconductor substrate and arranged in an array. The predetermined patterns 2 can be, for example, from an original database.

The first pattern file including a plurality of first patterns 31 is formed by the graphic data system. Each of the first patterns 31 extends along a first direction (e.g., the X direction shown in FIG. 4) and covers a corresponding predetermined pattern 2 arranged in a line along the first direction. An extending length along the first direction of each of the first patterns 31 is equal to or greater than a total width of the corresponding predetermined patterns 2 arranged in a line along the first direction. In the present embodiment, the first patterns 31 are in the form of straight lines and are arranged in parallel. In the present embodiment, a line width Dₗ₁ of each of the first patterns 31 is equal to a width D_{P1} perpendicular to the first direction of each of the predetermined patterns 2 arranged in a line. In one embodiment, a line width Dₗ₁ of each of the first patterns 31 can be not equal to (e.g., slightly greater than or slightly less than) a width D_{P1} perpendicular to the first direction of each of the predetermined patterns 2 arranged in a line before applying an optical proximity correction (OPC) process. In the present embodiment, the line width Dₗ₁ and the width D_{P1} each are a width along the Y direction. A first gap 32 is defined between two adjacent first patterns 31. A width D_{g1} of the first gap 32 depends on the line widths Dₗ₁ of the two adjacent corresponding first patterns 31 and a width S₁ along the first direction between two adjacent predetermined patterns 2 covered by the two adjacent first patterns 31.

The second pattern file including a plurality of second patterns 41 is formed by the graphic data system. Each of the second patterns 41 extends along a second direction (in the present embodiment, for example, the Y direction shown in FIG. 4) and covers the corresponding predetermined pattern 2 arranged in a line along the second direction. An extending length along the second direction of each of the second patterns 41 is equal to or greater than a total width of the predetermined patterns 2 arranged in a line along the second direction. In the present embodiment, the second patterns 41 are in the form of straight lines and are arranged in parallel. A line width Dₗ₂ of each of the second patterns 41 is equal to a width D_{P2} perpendicular to the second direction of each of the predetermined patterns 2 arranged in a line. In one embodiment, a line width Dₗ₂ of each of the second patterns 41 is not equal to (e.g., slightly greater than or slightly less than) a width D_{P2} perpendicular to the second direction of each of the predetermined patterns 2 arranged in a line before applying an optical proximity correction (OPC) process. In the present embodiment, the line width Dₗ₂ and the width D_{P2} each are a width along the X direction. The second patterns 41 are intersected with the first patterns 31. A second gap 42 is defined between two adjacent second patterns 41. A width D_{g2} of the second gap 42 depends on the line widths Dₗ₂ of the two adjacent second patterns 41 and a width S₂ along the second direction between two adjacent corresponding predetermined patterns 2 covered by the two adjacent second patterns 41. It is noted that, the width D_{g1} can be not equal to the width D_{g2}, and the width S₁ can be unequal to the width S₂.

When the first patterns 31 and the second patterns 41 are overlapped, a plurality of overlapped regions 5 are defined. In the present embodiment, because the second direction is perpendicular to the first direction and the first patterns 31 and the second patterns 41 are in the form of straight lines, the overlapped regions 5 are shaped square-like, thereby defining the square-like shaped predetermined patterns 2. In one embodiment, a line width Dₗ₁ of each of the first patterns 31 is not equal to a line width Dₗ₂ of each of the second patterns 41 the overlapped region 5 will become rectangle-like shaped. In other embodiments, the second direction is not perpendicular to the first direction and the first patterns 31 and the second patterns 41 are in the form of straight lines, the overlapped regions 5 can be parallelogrammic, thereby forming a plurality of parallelogrammic predetermined patterns.

In addition, the first pattern 31 and the second pattern 41 can be opaque or transparent. In the present embodiment, the first pattern 31 and the second pattern 41 is transparent. In one embodiment, the first pattern 31 and the second pattern 41 are opaque, and the overlapped regions can be shaped pillar-like. In another embodiment the overlapped regions can be any combination of the configurations as mentioned above.

Furthermore, referring to FIG. 4, in the present embodiment, the first pattern file further includes a plurality of first dummy patterns 33 and the second pattern file further includes a plurality of second dummy patterns 43. The first dummy patterns 33 are disposed beside the first patterns 31 and are disposed in a region without the first patterns 31. The second dummy patterns 43 are beside the second patterns 41 and are disposed in a region without the second patterns 41. The first dummy patterns 33 do not intersect with the second patterns 41 in the subsequent semiconductor process. The second dummy patterns 43 do not intersect with the first patterns 31 in the subsequent semiconductor process. Further, the second dummy patterns 43 do not intersect with the first dummy patterns 33.

The first dummy patterns 33 and the second dummy patterns 43 are configured for forming dummy patterns on the semiconductor substrate so as to protect the trenches during filling a dielectric material or a metal material layer and a flattening process, thereby avoiding a dishing problem in a region with low-density wiring pattern. In addition, the dummy patterns can be formed in an isolated space or a semi-isolated space of the wiring pattern of the semiconductor substrate so as to form a uniform density wiring pattern, thereby improving a tolerance range of the parameters of an etching process and depth of field (DOF) of a photolithography process and an accuracy of the critical dimension of the trenches. When the semiconductor substrate has a high-density wiring region, the first dummy patterns 33 and the second dummy patterns 43 correspond to a region outside the high-density wiring region and surround the high-density wiring region. Preferably, the first dummy patterns 33 are disposed to surround the first patterns 31, and the second dummy patterns 43 are disposed to surround the second patterns 41. In the present embodiment, two first dummy patterns 33 are designed to be parallel to the first patterns 31 and on two ends of all the first patterns 31 along the first direction, and two second dummy patterns 43 are designed to be parallel to the second patterns 41 and on two ends of all along the second direction.

In the present embodiment, a line width D_{d1} of each of the first dummy patterns 33 is greater than 20 nanometers, and a line width D_{d2} of each of the second dummy patterns 43 is greater than 20 nanometers. A width D_{g1} of the first gap 32 adjacent to the first dummy pattern 33 is, for example, less than 300 nanometers. Preferably, the width D_{g1} of the first gap 32 adjacent to the first dummy pattern 33 is less than 200 nanometers. A width D_{g2} of the second gap 42 adjacent to the second dummy pattern 43 is, for example, less than 300 nanometers. Preferably, the width D_{g2} of the second gap 42 adjacent to the second dummy pattern 43 is less than 200 nanometers. Thus, the dummy patterns formed will not affect the performance of the semiconductor device. In addition, each of the first dummy patterns 33 is adjacent to the first gap 32. When performing a photolithography process, the formation the dummy patterns will form a uniform density wiring pattern for subsequent processes. In other words, the dimensions of the first and second dummy patterns 33 and 43 depend on the first patterns 31, the second patterns 41, the first gaps 32, the second gaps 42 or other combination.

It is noted that, in other embodiment, only the first pattern file includes the first dummy patterns 33. It is also noted that, in other embodiment, only the second pattern file includes the second dummy patterns 43. That is, it is not necessary for the first dummy patterns 33 and the second dummy patterns 43 to form simultaneously.

In other words, in the pattern formation process 100, a photomask layout is formed. In the photomask formation process 200, the first patterns 31, the second pattern 41, the first dummy patterns 33 and the second dummy patterns 43 are transferred onto a substrate so as to form a first photomask and a second photomask according to the first pattern file and the second pattern file respectively. In the present embodiment, an e-beam writing system is used to transfer the first patterns 31, the second pattern 41, the first dummy patterns 33 and the second dummy patterns 43 to form the first photomask and the second photomask.

In the present embodiment, the first photomask and the second photomask each are a reticle. A size of the patterns on the reticle is usually about 5 times or 4 times the size of the patterns on a transferred substrate. For example, a line width D_{d1} of each of the first dummy patterns 33 is greater than 20 nanometers, a line width of a corresponding pattern transferred on the first photomask is equal to the line width D_{d1} of the corresponding first dummy patterns 33. Meanwhile, the line width of a corresponding pattern transferred on the first photomask is about 5 times or 4 times the line width of the photolithographed pattern on the transferred substrate (e.g., a semiconductor substrate).

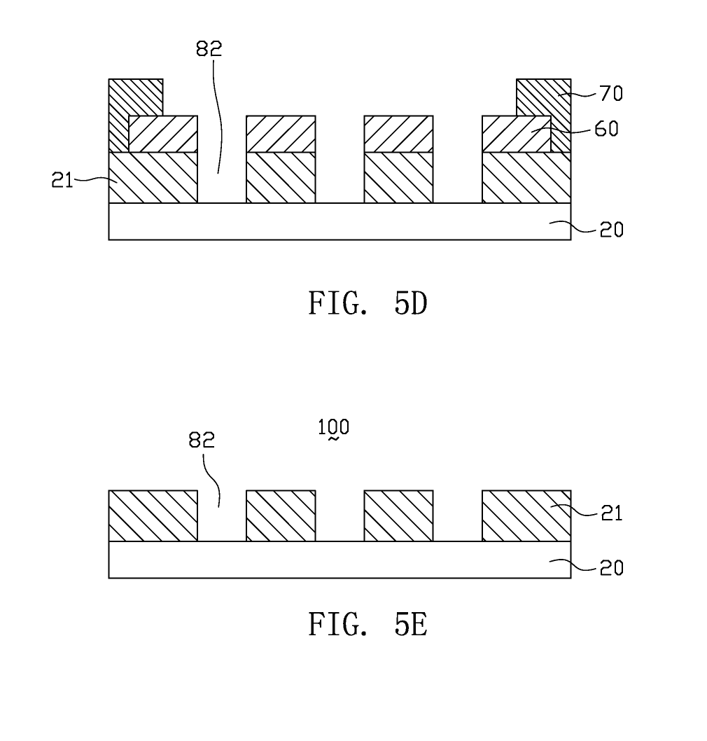

Next, the photolithography process 300 is performed by using the first photomask and the second photomask as described above. In the present embodiment, the size of the patterns on the first and second photomasks is about 4 times the size of the photolithographed pattern on the transferred substrate (e.g., a semiconductor substrate). FIG. 5A to FIG. 5E illustrate a process flow of the photolithography process in the semiconductor process.

Referring to FIG. 5A, a first material layer 21 is formed on a semiconductor substrate 20, and a second material layer 22 is formed on the first material layer 21 by chemical vapor deposition and has a thickness range may be between 50 Å.˜2000 Å. The first material layer 21 is made of, such as silicon dioxide, silicon nitride, oxidenitride, metal, polymer or a combination thereof. The first material layer 21 can be formed by any well-known method, and thus, the description concerning the known methods is omitted herein. The second material layer 22 is also made of the material, such as silicon dioxide, silicon nitride, oxidenitride, metal, polymer or a combination thereof. Preferably, the first material layer 21 and the second material layer 22 have different etching rates so that etching depth and position can be controlled.

In the present embodiment, first, a photoresist layer (not shown), for example, a positive photoresist layer, is applied to the second material layer 22. After a photolithography process using the first photomask as described above, the photoresist layer is patterned to form a patterned photoresist layer 55 having a plurality of patterns corresponding to the first patterns 31 and the dummy patterns 33. In the present embodiment, the size of the patterns on the first photomask is about 4 times the size of the patterns on a photoresist layer. The size of the patterns on a photoresist layer is a quarter of the size of the patterns on the first photomask.

Thereafter, referring to FIG. 5B, portions of the second material layer 22 uncovered by and exposed from the patterned photoresist layer 55 are etched, and then the patterned photoresist layer 55 is removed from the second material layer 22. The second material layer 22 is patterned to form a first pattern layer 60. As shown in FIG. 5B, the first pattern layer 60 has a plurality of first blocking parts 61 corresponding to the first gaps 32 and a plurality of first pattern openings 62 corresponding to the first patterns 31. It is noted that, the first dummy pattern 31 is also photolithographed to a dummy opening (not labeled) in the second material layer 22 correspondingly. In one embodiment, may be the first dummy patterns 31 are not printed by the lithography process. The purpose of first dummy patterns 31 here is for critical dimension control more accuracy.

Next, as shown in FIG. 5C, in the present embodiment, a third material layer (not shown) is formed on the first pattern layer 60, followed by a photolithography process using the second photomask as described above. In the present embodiment, the size of the patterns on the second photomask is about 4 times the size of the patterns on a third material layer. The size of the patterns on a third material layer is a quarter of the size of the patterns on the second photomask. As a result, the third material layer is patterned to form the second pattern layer 70. The second pattern layer 70 can be made of a photoresist material, for example, either a positive-type photoresist material or negative-type photoresist material. In the present embodiment, the second pattern layer 70 is made of a positive photoresist material. The second pattern layer 70 has a plurality of second blocking parts (not labeled) corresponding to the second gaps 42 and a plurality of second pattern openings not labeled corresponding to the second patterns 41. Because FIG. 5C is a cross-sectional view along one of the second pattern openings, the second blocking parts can not be shown. Referring to FIG. 5C together with FIG. 4, the first pattern openings 62 and second pattern openings intersect each other on the first material layer 21 and corporately define a plurality of uncovering regions 80 where they intersect. The uncovering regions 80 correspond to the overlapped regions 5 of the first patterns 31 of the first pattern file and the second patterns 32 of the second pattern file. It is noted that, the second dummy pattern 41 is also photolithographed to a dummy opening (not labeled) in the third material layer, thereby being photolithographed onto the first material layer 21 correspondingly without being covered by the second material layer 22.

Next, referring to FIG. 5C and FIG. 5D, portions 210 of the first material layer 21 in the uncovering regions 80 are exposed from the first pattern layer 60 and the second patterned layer 70 and are etched so that a plurality of trenches 82 are formed in the first material layer 21 as shown in FIG. 5E. In the present embodiment, a projection of each of the trenches 82 on the semiconductor substrate 20 is, but not limited to, square-like shaped.

Thereafter, the second pattern layer 70 and the first pattern layer 60 are removed in sequence by using one of plasma, at least one of wet or dry etching, and chemical mechanical polishing. After removing the first and second patterns layer 60, 70, a semiconductor chip 100 shown in FIG. 5E is formed.

It should be noted that, the pitch of at least one of the first pattern layer 60 and the second pattern layer 70 is not larger than 140 nm. The pitch of the first pattern layer 60 is defined as the width along the first direction (i.e, the X direction) of one of the first blocking parts 61 plus the width along the first direction (i.e, the X direction) of one of the first gaps 62. The pitch of the second pattern layer 70 is defined as the width along the second direction (i.e, the Y direction) of one of the second blocking parts plus the width along the second direction (i.e, the X direction) of one of the second gaps. When the pitches of the first and second pattern layers 60, 70 both are larger than 140 nm, may be it is not necessary to use a dummy pattern for double patterning lithography according to the present invention.

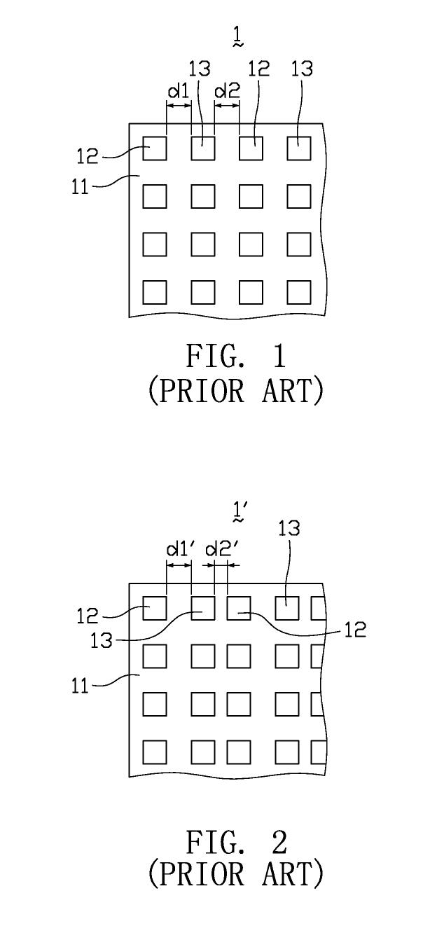

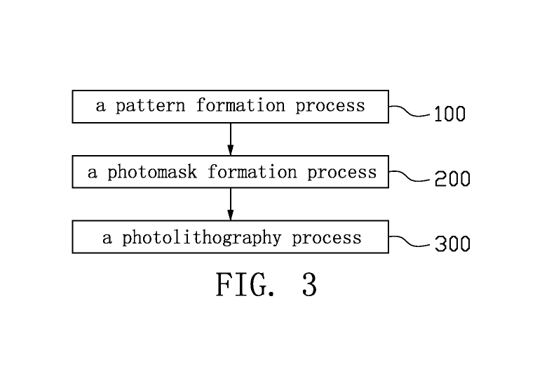

Since the trenches 82 are formed at intersection points of the first pattern openings 62 and second pattern openings by combining two photolithography processes, and since the first blocking parts 61 and second blocking parts are formed as lines which are sized to be smaller than 140 nm only in their width directions (i.e. one of the X direction or Y direction), the first and second pattern layers 60, 70 can be provided with a photolithography resolution higher than that of the resist patterns used in the prior art (see FIGS. 1 and 2) and having trench dimensions smaller than 140 nm in both the X direction and the Y direction. Accordingly, the method of the present invention has an improved CD shrinkage function. In addition, the shape of the trenches 82 is less irregular than that of the trenches 12, 13 formed in the prior art, and in the present embodiment, each trench 82 can have right angles at four corners.

On the other hand, when the first pattern layer 60 or the second pattern layer 70 displaces from its pre-designed position in case of an overlay error, all of the uncovering regions 80 will shift in the same direction (the X direction or the Y direction) and by the same distance. Therefore, the dimension of the uncovering regions 80 will not deviate from the pre-designed dimension, thereby eliminating the problem of dimensional variation encountered by the trenches 12, 13 of the prior art as shown in FIG. 2.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for double patterning lithography, which is applied to a semiconductor substrate to form a plurality of trenches, comprising:
a pattern formation process comprising:
forming a plurality of predetermined patterns corresponding to the trenches by using a graphic data system;
forming a first pattern file by using the graphic data system, the first pattern files comprising a plurality of first patterns; and
forming a second pattern file by using the graphic data system, the second pattern files comprising a plurality of second patterns;
wherein at least one of the first pattern file and the second pattern file comprises a plurality of dummy patterns therebeside, and only the first patterns and the second patterns are intersected with each other to define a plurality of overlapped regions corresponding to the predetermined patterns during overlapping the first patterns and the second patterns.

2. The method of claim 1, wherein the first patterns extend along a first direction and cover the corresponding predetermined patterns arranged in a line along the first direction, and the second patterns extend along a second direction and cover the corresponding predetermined pattern arranged in a line along the second direction.

3. The method of claim 2, wherein an extending length along the first direction of each of the first patterns is either equal to or great than a total width of the corresponding predetermined patterns arranged in the line along the first direction, and an extending length along the second direction of each of the second patterns is either equal to or great than a total width of the corresponding predetermined patterns arranged in the line along the second direction.

4. The method of claim 2, wherein the first direction is perpendicular to the second direction.

5. The method of claim 3, wherein a line width of each of the first patterns is substantially equal to a width perpendicular to the first direction of each of the corresponding predetermined patterns arranged in the line along the first direction.

6. The method of claim 3, wherein a line width of each of the first patterns is not equal to a width perpendicular to the first direction of each of the corresponding predetermined patterns arranged in the line along the first direction.

7. The method of claim 3, wherein a line width of each of the second patterns is substantially equal to a width perpendicular to the second direction of each of the corresponding predetermined patterns arranged in the line along the second direction.

8. The method of claim 3, wherein a line width of each of the second patterns is not equal to a width perpendicular to the second direction of each of the corresponding predetermined patterns arranged in the line along the second direction.

9. The method of claim 1, wherein the dummy patterns comprise a plurality of first dummy patterns, the first patterns and the first dummy patterns constitute the first pattern file, the first dummy patterns beside the first patterns and are not intersected with the second patterns.

10. The method of claim 9, wherein the semiconductor substrate has a high-density wiring region, the first dummy patterns correspond to a region outside the high-density wiring region and surround the high-density wiring region.

11. The method of claim 1, wherein the dummy patterns comprises a plurality of first dummy patterns and a plurality of second dummy patterns, the first patterns and the first dummy patterns constitute the first pattern file, the second patterns and the second dummy patterns constitute the second pattern file, the first dummy patterns beside the first patterns and are not intersected with the second patterns and second dummy patterns, and the second dummy patterns beside the second patterns and are not intersected with the first patterns and the first dummy patterns.

12. The method of claim 11, wherein the semiconductor substrate has a high-density wiring region, the first dummy patterns and the second dummy patterns correspond to a region outside the high-density wiring region and surround the high-density wiring region.

13. The method of claim 1, further comprising a photomask formation process and a photolithography process.

14. A photomask layout for double patterning lithography, which is configured for forming a plurality of predetermined patterns, comprising:
a plurality of first patterns;
a plurality of second patterns; and
a plurality of dummy patterns beside at least one of the first patterns and the second patterns;
wherein only the first patterns and the second patterns are intersected with each other to define a plurality of overlapped regions corresponding to the predetermined patterns during overlapping the first patterns and the second patterns.

15. The photomask layout for double patterning lithography of claim 14, wherein the first patterns extend along a first direction and cover the corresponding predetermined patterns arranged in a line along the first direction, and the second patterns extend along a second direction and cover the corresponding predetermined pattern arranged in a line along the second direction.

16. The photomask layout for double patterning lithography of claim 15, wherein an extending length along the first direction of each of the first patterns is either equal to or great than a total width of the corresponding predetermined patterns arranged in the line along the first direction, and an extending length along the second direction of each of the second patterns is either equal to or great than a total width of the corresponding predetermined patterns arranged in the line along the second direction.

17. The photomask layout for double patterning lithography of claim 14, wherein the first direction is perpendicular to the second direction.

18. The photomask layout for double patterning lithography of claim 14, wherein the dummy patterns comprise a plurality of first dummy patterns, the first dummy patterns are beside the first patterns and are not intersected with the second patterns.

19. The photomask layout for double patterning lithography of claim 14, wherein the dummy patterns further comprise a plurality of second dummy patterns, the second dummy patterns are beside the second patterns and are not intersected with the first patterns and the first dummy patterns.
